(19) United States
(12) Patent Application Publication
(10) Pub. No.: US 2025/0248313 A1
(43) Pub. Date: Jul. 31, 2025

(54) MAGNETO-RESISTIVE ELEMENT

(71) Applicant: TDK CORPORATION, Tokyo (JP)

(72) Inventors: Kazuumi INUBUSHI, Tokyo (JP); Katsuyuki NAKADA, Tokyo (JP)

(73) Assignee: TDK CORPORATION, Tokyo (JP)

(21) Appl. No.: 18/425,752

(22) Filed: Jan. 29, 2024

(51) Int. Cl. H10N 50/10; H10N 50/85

(52) U.S. Cl. CPC H10N 50/10; H10N 50/85

(57) ABSTRACT

A magneto-resistive element includes a substrate, first ferromagnetic layer, non-magnetic metal layer, second ferromagnetic layer, third ferromagnetic layer, metal oxide layer, fourth ferromagnetic layer, and antiferromagnetic layer. The first and second ferromagnetic layers include a Heusler alloy containing Co. The non-magnetic metal layer is located between the first and second ferromagnetic layers. The second ferromagnetic layer is closer to the substrate than the first. The third ferromagnetic layer is located between the second ferromagnetic layer and the metal oxide layer. The metal oxide layer has a spinel crystal structure and is located between the third and fourth ferromagnetic layers. The fourth ferromagnetic layer is amorphous containing B and Ta, and is located between the metal oxide layer and the antiferromagnetic layer. At least a part of the metal oxide layer, the third ferromagnetic layer, the second ferromagnetic layer, the non-magnetic metal layer, and the first ferromagnetic layer are continuously crystallized.

### BACKGROUND OF THE INVENTION

### Field of the Invention

The present disclosure relates to a magneto-resistive element.

### Description of Related Art

A magneto-resistive element is an element whose resistance value in the lamination direction changes due to a magneto-resistive effect. A magneto-resistive element includes two ferromagnetic layers and a nonmagnetic layer sandwiched between them. A magneto-resistive element that uses a conductor as a non-magnetic layer is referred to as a giant magneto-resistive (GMR) element, and a magneto-resistive element that uses an insulating layer (a tunnel barrier layer, a barrier layer) as a non-magnetic layer is referred to as a tunnel magneto-resistive (TMR) element. Magneto-resistive elements can be applied in various applications such as magnetic sensors, high-frequency components, magnetic heads, and nonvolatile random access memories (MRAM).

Patent Document 1 discloses a magneto-resistive element using a Heusler alloy as a ferromagnetic layer. A Heusler alloy has high spin polarizability. Magnetic sensors containing Heusler alloys are expected to have large output signals. To realize these expected properties, it is necessary to convert a Heusler alloy into a crystal. In Patent Document 1, crystallization of a Heusler alloy is realized by using a MgO film as a base layer.

### PATENT DOCUMENTS

[Patent Document 1] Japanese Unexamined Patent Application, First Publication No. 2013-247259

### SUMMARY OF THE INVENTION

The magneto-resistive element described in Patent Document 1 has a top pin structure in which a fixed layer is located farther from a substrate than a first CoFeB film. The magneto-resistive element of the top pin structure cannot be applied to a read head for a hard disk.

Furthermore, a MgO film used in the magneto-resistive element described in Patent Document 1 has high insulation properties. A magneto-resistive element using a MgO film has a large area resistance (hereinafter referred to as RA, which is Resistance Area product). A read head for a high-density hard disk requires a low RA magneto-resistive element.

This magneto-resistive element includes a substrate, a first ferromagnetic layer, a non-magnetic metal layer, a second ferromagnetic layer, a third ferromagnetic layer, a metal oxide layer, a fourth ferromagnetic layer, and an antiferromagnetic layer. The first ferromagnetic layer includes a Heusler alloy containing Co. The non-magnetic metal layer is located between the first ferromagnetic layer and the second ferromagnetic layer in a lamination direction. The second ferromagnetic layer includes a Heusler alloy containing Co, and is located closer to the substrate than the first ferromagnetic layer. The third ferromagnetic layer is located between the second ferromagnetic layer and the metal oxide layer in the lamination direction. The metal oxide layer has a spinel crystal structure and is located between the third ferromagnetic layer and the fourth ferromagnetic layer in the lamination direction. The fourth ferromagnetic layer is amorphous, contains B and Ta, and is located between the metal oxide layer and the antiferromagnetic layer in the lamination direction. At least a part of the metal oxide layer, the third ferromagnetic layer, the second ferromagnetic layer, the non-magnetic metal layer, and the first ferromagnetic layer are continuously crystallized.

### BRIEF DESCRIPTION OF THE DRAWINGS

FIG. 1 is a cross-sectional view of a magneto-resistive element according to a first embodiment.

FIG. 2A is a diagram which shows a crystal structure of a Heusler alloy.

FIG. 2B is a diagram which shows a crystal structure of a Heusler alloy.

FIG. 2C is a diagram which shows a crystal structure of a Heusler alloy.

FIG. 2D is a diagram which shows a crystal structure of a Heusler alloy.

FIG. 2E is a diagram which shows a crystal structure of a Heusler alloy.

FIG. 2F is a diagram which shows a crystal structure of a Heusler alloy.

FIG. 3 is a conceptual diagram of an atomic arrangement of the magneto-resistive element according to the first embodiment.

FIG. 4 is a cross-sectional view of a magnetic recording element according to application example 1.

FIG. 5 is a cross-sectional view of the magnetic recording element according to application example 2.

FIG. 6 is a cross-sectional view of a high frequency device according to application example 3.

### DETAILED DESCRIPTION OF THE INVENTION

Hereinafter, the present embodiment will be described in detail with reference to drawings as appropriate. In the drawings used in the following description, characteristic parts may be shown enlarged for convenience to make features of the present embodiment easier to understand, and dimensional ratios of each component may differ from the actual ones. The materials, dimensions, and the like exemplified in the following description are merely examples, and the present disclosure is not limited thereto, and can be implemented with appropriate changes without changing the gist thereof.

### First Embodiment

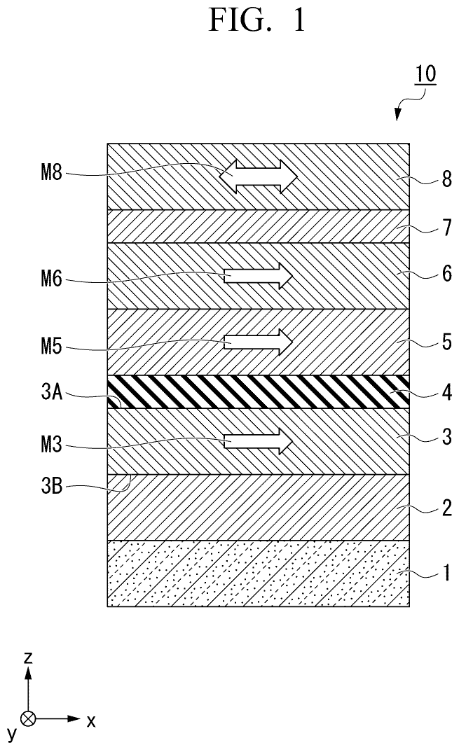

FIG. 1 is a cross-sectional view of a magneto-resistive element according to the first embodiment. First, directions will be defined. A lamination direction of each layer is sometimes referred to as a z direction. Moreover, a direction that intersects the z direction and in which each layer spreads is referred to as an in-plane direction, one direction is referred to as an x direction, and a direction orthogonal to the x direction and the z direction is referred to as a y direction.

The magneto-resistive element 10 includes a substrate 1, an antiferromagnetic layer 2, a fourth ferromagnetic layer 3, a metal oxide layer 4, a third ferromagnetic layer 5, a second ferromagnetic layer 6, a non-magnetic metal layer 7, and a first ferromagnetic layer 8. The magneto-resistive element 10 outputs a change in relative angle between magnetization M8 of the first ferromagnetic layer 8 and magnetization M6 of the second ferromagnetic layer 6 as a resistance value change.

The substrate 1 does not particularly matter. The substrate may have crystallinity or may be amorphous. For example, metal oxide single crystal, silicon single crystal, and sapphire single crystal are examples of substrates having crystallinity. For example, silicon single crystal with a thermal oxide film, glass, ceramic, and quartz are examples of amorphous substrates.

The antiferromagnetic layer 2 is on the substrate 1. The antiferromagnetic layer 2 may be directly laminated on the substrate 1, or may be laminated between the antiferromagnetic layer 2 and the substrate 1 with another layer interposed therebetween. The antiferromagnetic layer is, for example, IrMn, PtMn, or the like.

The fourth ferromagnetic layer 3 is on the antiferromagnetic layer 2. The fourth ferromagnetic layer 3 is between the antiferromagnetic layer 2 and the metal oxide layer 4 in the z-direction.

The fourth ferromagnetic layer 3 includes an amorphous ferromagnetic material containing B and Ta. The fourth ferromagnetic layer 3 includes, for example, Co, Fe, B, and Ta. The fourth ferromagnetic layer 3 is, for example, CoFeBTa. Composition ratios of each of Co, Fe, B, and Ta do not matter.

A concentration of boron in the fourth ferromagnetic layer 3 does not have to be constant. For example, the boron concentration in a first surface 3A may be higher than that in a second surface 3B. The first surface 3A is a surface of the fourth ferromagnetic layer 3 that is in contact with the metal oxide layer 4, and the second surface 3B is a surface opposite to the first surface 3A.

When the boron concentration in the first surface 3A on a side of the metal oxide layer 4, which is crystallized by annealing, is high, the fourth ferromagnetic layer 3 can easily maintain an amorphous state. Since the fourth ferromagnetic layer 3 is amorphous, when a layer above the metal oxide layer 4 is crystallized, it can be crystallized without being affected by the fourth ferromagnetic layer 3, and the layer above the metal oxide layer 4 is easily crystallized continuously.

The metal oxide layer 4 is between the fourth ferromagnetic layer 3 and the third ferromagnetic layer 5 in the z direction. The metal oxide layer 4 is on the fourth ferromagnetic layer 3.

The metal oxide layer 4 has a spinel crystal structure. The metal oxide layer 4 is made of, for example, an oxide containing one or more divalent elements and trivalent elements selected from the group consisting of Mg, Al, Ga, Ti, In, Sn, Zn, Ge, Ag, Cu, Mn, Si, In, Pt, Cr, V, Rh, Mo, W, Fe, Co, and Ni. An oxide constituting the metal oxide layer 4 may have a spinel structure. The spinel structure is not limited to a normal spinel structure, but may also be a reverse spinel structure.

The metal oxide layer 4 has, for example, a composition formula AₓBₓ₋₁O_{y} (A=Mg, Sn, Zn, Ge, Cu, Mn, Si, Ti, Pt, V, Fe, Co; B=Al, Ga, In, Sn, Ge, Ag, Cu, Mn, Ti, Cr, V, Rh, Mo, W, Fe, Ni; 0≤x≤1; 0.133≤y<1.2), where A is a divalent cation element and B is a trivalent cation. The metal oxide layer 4 contains, for example, Mg—Al—O. Mg—Al—O is an oxide of Mg and Al, and its stoichiometric composition is expressed as MgAl₂O₄.

The metal oxide constituting the metal oxide layer 4 may have a ratio of oxygen in a composition formula higher than a total ratio of metal elements when expressed in stoichiometric composition. “The ratio of oxygen and the total ratio of metal elements in the composition formula when expressed in the stoichiometric composition” is obtained by the following procedure. For example, in the case of a compound whose stoichiometric composition is represented by MgAl₂O₄, a composition ratio of Mg, Al, and O is 1:2:4. The ratio of oxygen in the composition formula is 4, and the total ratio of metal elements in the composition formula is 3. In other words, MgAl₂O₄ corresponds to a material in which the ratio of oxygen in the composition formula is higher than the total ratio of metal elements when expressed in the stoichiometric composition. When this configuration is satisfied, the metal oxide is in a stable state in which it is sufficiently oxidized, and easily becomes a spinel crystal structure when crystallized, and also becomes a stable spinel crystal structure after crystallization.

A barrier height of the metal oxide constituting the metal oxide layer 4 may be set lower than a barrier height of MgO having the same film thickness. For example, the barrier height of the metal oxide constituting the metal oxide layer 4 may be set to 7.1 eV or less. The barrier height is an energy required to allow electrons to pass through. If the barrier height is lower, the resistivity is lowered.

The barrier height of the metal oxide can be controlled by controlling a composition of elements that constitute the metal oxide and a film quality of the metal oxide layer. By controlling the barrier height of the metal oxide layer 4, an RA of an entire magneto-resistive element 10 can be lowered.

In addition, resistivity of the metal oxide layer 4 may be higher than that of the non-magnetic metal layer 7. The resistivity referred to herein is inherent resistivity of a composition having a certain chemical composition, and its unit is Q cm. Resistivity is a physical property value that does not depend on a shape or dimension of a conductor. Resistivity can be obtained from an actually measured value of the resistivity of a target layer. Even if it is difficult to measure the actually measured value, it is possible to obtain the inherent resistivity of the metal oxide by forming a layer of the same composition by a known method (for example, a film is formed with a thickness of 5 m on a suitable substrate) and measuring a measured value of resistivity of the film.

The resistivity of the metal oxide layer 4 can be changed by changing an oxygen vacancy rate of the metal oxide and a film quality of the metal oxide layer 4. By adjusting the resistivity of the metal oxide layer 4, the RA of the entire magneto-resistive element 10 can be designed.

A film thickness of the metal oxide layer 4 is, for example, thinner than that of the non-magnetic metal layer 7. The film thickness of the metal oxide layer 4 is, for example, 1.5 nm or less. When the film thickness of the metal oxide layer 4 is sufficiently thin, magnetic coupling between the fourth ferromagnetic layer 3 and the third ferromagnetic layer 5 becomes strong. When the magnetic coupling between these layers is strong, magnetization stability of the fourth ferromagnetic layer 3, the third ferromagnetic layer 5, and the second ferromagnetic layer 6 increases. Moreover, if the film thickness of the metal oxide layer 4 is sufficiently thin, a resistance value of the metal oxide layer 4 becomes small, and the RA of the entire magneto-resistive element 10 can be lowered.

The third ferromagnetic layer 5 is between the metal oxide layer 4 and the second ferromagnetic layer 6 in the z direction. The third ferromagnetic layer 5 is laminated on the metal oxide layer 4.

The third ferromagnetic layer 5 contains Co and Fe. The third ferromagnetic layer 5 is, for example, Co—Fe or Co—Fe—B. An alloy containing Co and Fe has a lattice constant close to a lattice constant of a crystal in a spinel structure, and is easily lattice-matched to the metal oxide layer 4 of the spinel structure. The third ferromagnetic layer 5 is lattice-matched to the metal oxide layer 4, thereby promoting crystallization of the layer above the third ferromagnetic layer 5.

A film thickness of the third ferromagnetic layer 5 is, for example, 1.5 nm or more. When the film thickness of the third ferromagnetic layer 5 is sufficiently thick, magnetization of the third ferromagnetic layer 5 is easily oriented in an xy plane. Magnetization M5 of the third ferromagnetic layer 5 and magnetization M3 of the fourth ferromagnetic layer 3 are magnetically coupled. This magnetic coupling may be ferromagnetic coupling or antiferromagnetic coupling.

The second ferromagnetic layer 6 is located between the third ferromagnetic layer 5 and the non-magnetic metal layer 7 in the z direction. The second ferromagnetic layer 6 is located closer to the substrate 1 than the first ferromagnetic layer 8. The second ferromagnetic layer 6 is laminated on the third ferromagnetic layer 5.

Magnetization M6 of the second ferromagnetic layer 6 is, for example, more difficult to move than magnetization M8 of the first ferromagnetic layer 8. When a predetermined external force is applied, a direction of the magnetization M6 of the second ferromagnetic layer 6 does not change (is fixed), and a direction of the magnetization M8 of the first ferromagnetic layer 8 changes. The second ferromagnetic layer 6 is sometimes referred to as a fixed layer or a reference layer, and the first ferromagnetic layer 8 is sometimes referred to as a free layer. The magnetization M6 of the second ferromagnetic layer 6 is oriented in the same direction as the magnetization M5 of the third ferromagnetic layer 5. The magnetization M6 of the second ferromagnetic layer 6 is fixed more than the magnetization M8 of the first ferromagnetic layer 8 by the magnetization M5 of the third ferromagnetic layer 5 and the magnetization M3 of the fourth ferromagnetic layer 3.

The second ferromagnetic layer 6 includes, for example, an Heusler alloy containing Co. The Heusler alloy is an intermetallic compound with a chemical composition of XYZ or X₂YZ. A ferromagnetic Heusler alloy expressed as X₂YZ is referred to as a full Heusler alloy, and a ferromagnetic Heusler alloy expressed as XYZ is referred to as a half Heusler alloy. A half Heusler alloy is a full Heusler alloy in which some of atoms at an X site are vacant.

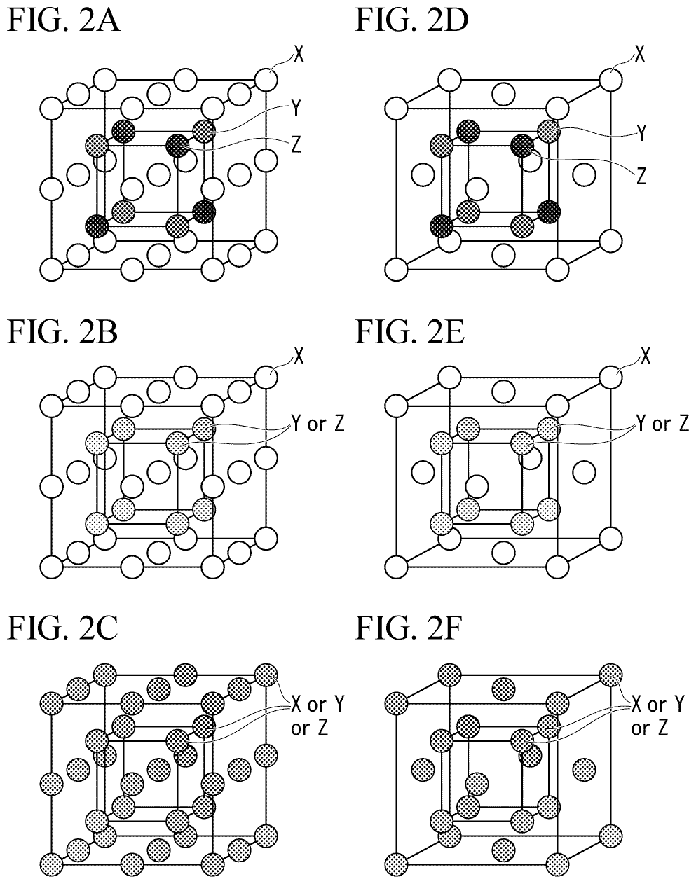

FIGS. 2A to 2F are examples of a crystal structure of the Heusler alloy. FIGS. 2A, 2B, and 2C are examples of a crystal structure of the full Heusler alloy, and FIGS. 2D, 2E, and 2F are examples of a crystal structure of the half Heusler alloy.

FIG. 2A is referred to as an L2₁ structure. In the L2₁ structure, elements that enter the X site, elements that enter a Y site, and elements that enter a Z site are fixed. FIG. 2B is referred to as a B2 structure derived from an L2₁ structure. In the B2 structure, the elements that enter the Y site and the elements that enter the Z site are mixed, and the elements that enter the X site are fixed. FIG. 2C is referred to as an A2 structure derived from the L2₁ structure. In the A2 structure, the elements that enter the X site, the elements that enter the Y site, and the elements that enter the Z site are mixed.

FIG. 2D is referred to as a C1_{b} structure. In the C1_{b} structure, the elements that enter the X site, the elements that enter the Y site, and the elements that enter the Z site are fixed. FIG. 2E is referred to as a B2 structure derived from the C1_{b} structure. In the B2 structure, the elements that enter the Y site and the elements that enter the Z site are mixed, and the elements that enter the X site are fixed. FIG. 2F is referred to as a A2 structure derived from the C1_{b} structure. In the A2 structure, the elements that enter the X site, the elements that enter the Y site, and the elements that enter the Z site are mixed.

In the full Heusler alloy, crystallinity is higher in order of the L2₁ structure>the B2 structure>the A2 structure, and crystallinity is higher in order of the C1_{b} structure>the B2 structure>the A2 structure in the half Heusler alloy. Although these crystal structures differ in their crystal properties, they are all crystals.

At least a portion of the second ferromagnetic layer 6 is crystallized. The second ferromagnetic layer 6 may be, for example, entirely crystallized. The second ferromagnetic layer 6 has, for example, any of the crystal structures described above. A crystal structure of the second ferromagnetic layer 6 is, for example, a L2₁ structure or B2 structure.

Whether a Heusler alloy is crystallized can be determined by transmission electron microscopy (TEM) images (for example, high-angle scattering annular dark-field scanning transmission microscopy images: HAADF-STEM images) or electron diffraction images using transmission electron beams. When the Heusler alloy is crystallized, for example, atoms can be seen regularly arranged in a HAADF-STEM image. More specifically, spots originating from a crystal structure of the Heusler alloy appear in a Fourier transform image of the HAADF-STEM image. Moreover, when the Heusler alloy is crystallized, a diffraction spot from at least one of the (001) plane, (002) plane, (110) plane, (111) plane, and (011) plane can be confirmed in the electron beam diffraction image. If crystallization can be confirmed by at least one of the methods, it can be said that at least a part of the Heusler alloy has been crystallized.

In a composition formula of the Heusler alloy, X is a transition metal element or noble metal element of the Co, Fe, Ni, or Cu group on a periodic table, Y is a transition metal of the Mn, V, Cr or Ti group or an element species of X, and Z is a typical element of groups III to V. If the Heusler alloy contains Co, then X is Co.

A Heusler alloy containing Co is, for example, expressed as Co₂Y_{α}Z_{β}. Y is, for example, one or more elements selected from a group consisting of Fe, Mn, and Cr, and Z is, for example, one or more elements selected from a group consisting of Si, Al, Ga, and Ge, and α+β>2 is satisfied. Y is particularly preferably Fe, and Z is particularly preferably Ga and Ge. For example, a satisfies 0.3<α<2.1, more preferably satisfies 0.4<α<2.0. β satisfies 0.1≤β≤2.0.

A full Heusler alloy in the stoichiometric composition is expressed as Co₂YZ. When α+β>2 is satisfied, a Co composition ratio becomes relatively smaller than a sum of composition ratios of Y site and Z site elements. When the Co composition ratio is relatively smaller than the sum of the composition ratios of the Y site and Z site elements, an anti-site in which the Y site and Z site elements are replaced by the X site element (Co) can be avoided. The anti-site causes a Fermi level of the Heusler alloy to fluctuate. When the Fermi level fluctuates, a half-metallicity of the Heusler alloy decreases, and the spin polarizability decreases. A decrease in spin polarizability causes a decrease in the MR ratio of the magneto-resistive element 10.

The Heusler alloy containing Co may be expressed as, for example, Co₂Fe_{α}Ga_{β1}Ge_{β2}. The composition formula may satisfy α+β1+β2≥2.3, α<β1+β2, 0.5<α<1.9, 0.1≤β1, and 0.1≤β2.

Examples of the full Heusler alloy containing Co may include, for example, Co₂FeSi, Co₂FeAl, Co₂FeGeₓGa₁₋ₓ, Co₂MnGeₓGa₁₋ₓ, Co₂MnSi, Co₂MnGe, Co₂MnGa, Co₂MnSn, Co₂MnAl, Co₂CrAl, Co₂VAl, Co₂Mn₁₋ₐFeₐAl_{b}Si_{1-b}, and the like. The half Heusler alloy containing Co may be, for example, CoFeSb or CoMnSb.

The non-magnetic metal layer 7 is located between the first ferromagnetic layer 8 and the second ferromagnetic layer 6 in the z direction. The non-magnetic metal layer 7 is laminated on the second ferromagnetic layer 6. A thickness of the non-magnetic metal layer 7 is, for example, within a range of 1 nm or more and 10 nm or less. The non-magnetic metal layer 7 inhibits magnetic coupling between the first ferromagnetic layer 8 and the second ferromagnetic layer 6.

The non-magnetic metal layer 7 includes, for example, a non-magnetic metal. The non-magnetic metal layer 7 is made of, for example, a non-magnetic metal. The non-magnetic metal layer 7 is, for example, a metal or alloy containing any elements selected from a group consisting of Cu, Au, Ag, Al, and Cr. Metals or alloys containing these elements have excellent conductivity and lower the RA of the magneto-resistive element 10.

The non-magnetic metal layer 7 contains, for example, any atoms selected from the group consisting of Cu, Au, Ag, Al, and Cr as main constituent atoms. The main constituent atoms mean that a proportion of Cu, Au, Ag, Al, and Cr is 50% or more in the composition formula. The non-magnetic metal layer 7 preferably contains Ag or Cu as a main constituent atom, and particularly preferably contains Ag as a main constituent atom. Since Ag has a long spin diffusion length, the magneto-resistive element 10 using Ag shows a large MR ratio. The non-magnetic metal layer 7 is, for example, Ag or AgSn.

The first ferromagnetic layer 8 is laminated on the non-magnetic metal layer 7. An orientation direction of the magnetization M8 of the first ferromagnetic layer 8 changes regardless of an orientation direction of the magnetization M6 of the second ferromagnetic layer 6. By changing the orientation direction of the magnetization M8 of the first ferromagnetic layer 8, a resistance value in the lamination direction of the magneto-resistive element 10 changes. The magneto-resistive element 10 holds data as a resistance value in the lamination direction.

The first ferromagnetic layer 8 includes, for example, a Heusler alloy containing Co. The Heusler alloy constituting the first ferromagnetic layer 8 is the same as the Heusler alloy constituting the second ferromagnetic layer 6.

At least a part of the first ferromagnetic layer 8 is crystallized. The first ferromagnetic layer 8 may be, for example, entirely crystallized. A crystal structure of the first ferromagnetic layer 8 is, for example, an L2₁ structure or a B2 structure.

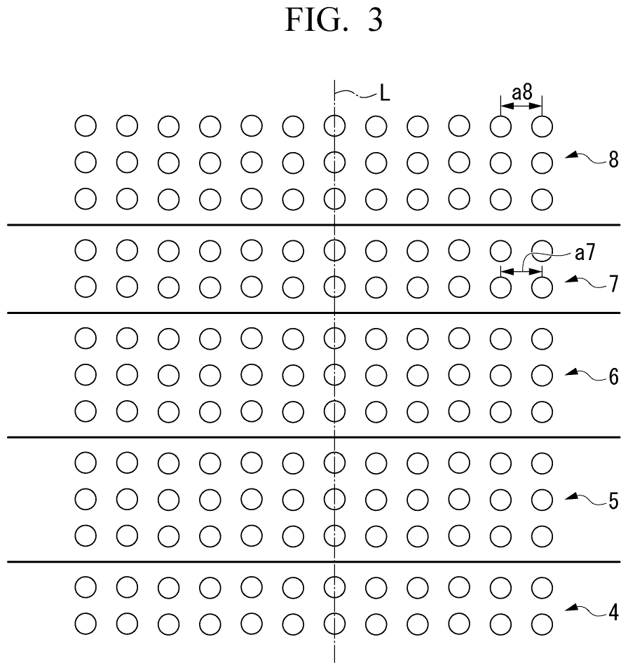

FIG. 3 is a conceptual diagram of an atomic arrangement of the magneto-resistive element 10 according to the first embodiment. As shown in FIG. 3, at least a part of the metal oxide layer 4, the third ferromagnetic layer 5, the second ferromagnetic layer 6, the non-magnetic metal layer 7, and the first ferromagnetic layer 8 are continuously crystallized.

Here, “continuous crystallization” can be confirmed by a continuous arrangement of atoms in a transmission electron microscope (TEM) image. When the metal oxide layer 4, the third ferromagnetic layer 5, the second ferromagnetic layer 6, the non-magnetic metal layer 7, and the first ferromagnetic layer 8 are continuously crystallized, if the arrangement of atoms is checked in order from a bottom layer, a line L where the atoms are lined up in a row can be drawn as shown in FIG. 3.

In the metal oxide layer 4, the third ferromagnetic layer 5, the second ferromagnetic layer 6, the non-magnetic metal layer 7, and the first ferromagnetic layer 8, a lattice mismatch between adjacent layers is, for example, less than 10%. For example, the lattice mismatch between the first ferromagnetic layer 8 and the non-magnetic metal layer 7 is obtained by dividing (a “lattice constant a8 of the first ferromagnetic layer 8”-a “lattice constant a7 of the non-magnetic metal layer 7”) by the “lattice constant a7 of the non-magnetic metal layer 7.” When the lattice mismatch at an interface is within the range described above, each layer or region becomes continuously crystallized.

A part of the metal oxide layer 4, the third ferromagnetic layer 5, the second ferromagnetic layer 6, the non-magnetic metal layer 7, and the first ferromagnetic layer 8, which are continuously crystallized, have a main orientation (also referred to as a preferential orientation) in (100). Being mainly oriented in the (100) direction means that a main crystal direction of crystals constituting the Heusler alloy is the (100) direction. For example, when the first ferromagnetic layer 8 is composed of a plurality of crystal grains, crystal directions of each crystal grain may be different. In this case, if a direction of the composite vector of crystal orientation directions in any 50 crystal grains is within a range of inclination of 25 degrees with respect to the (100) direction, it can be said that the main orientation is in the (100) direction. Here, an orientation direction considered to be equivalent to the (100) direction is also included in the (100) orientation. That is, the (100) orientation includes all of a (001) orientation, a (010) orientation, a (100) orientation, and orientation directions exactly opposite to these orientations. The magneto-resistive element 10 in which each layer is oriented in the same direction has a high MR ratio.

Composition of each layer can be determined using energy dispersive X-ray analysis (EDS). In addition, by performing an EDS line analysis, for example, a composition distribution of each material in the film thickness direction can be confirmed.

The magneto-resistive element 10 may have a layer other than those layers described above. For example, a base layer may be provided between the substrate 1 and the antiferromagnetic layer 2, and a cap layer may be provided above the first ferromagnetic layer 8. The base layer and the cap layer improve a crystal orientation in the first ferromagnetic layer 8 and the second ferromagnetic layer 6. The base layer and the cap layer contain, for example, Ru, Ir, Ta, Ti, Al, Au, Ag, Pt, and Cu. In addition, an NiAl layer is provided between the first ferromagnetic layer 8 and the non-magnetic metal layer 7 or between the second ferromagnetic layer 6 and the non-magnetic metal layer 7 as a layer for improving lattice matching.

Next, a method for manufacturing the magneto-resistive element 10 will be described. First, the substrate will be prepared.

Next, the antiferromagnetic layer 2, the fourth ferromagnetic layer 3, the metal oxide layer 4, the third ferromagnetic layer 5, the second ferromagnetic layer 6, the non-magnetic metal layer 7, and the first ferromagnetic layer 8 are sequentially formed on the substrate. Each layer is formed by, for example, a sputtering method.

The fourth ferromagnetic layer 3 is, for example, a Co—Fe—B—Ta layer. When the fourth ferromagnetic layer 3 is a Co—Fe—B—Ta layer, the fourth ferromagnetic layer 3 becomes amorphous at the time of film formation, and remains stably amorphous even after annealing. Boron contained in the fourth ferromagnetic layer 3 contains boron diffused from the third ferromagnetic layer 5 during annealing after film formation. In addition, the third ferromagnetic layer 5 is formed as, for example, a Co—Fe—B layer at the time of film formation. Boron contained in the third ferromagnetic layer 5 is attracted to Ta and the like contained in the fourth ferromagnetic layer 3 during annealing after film formation, and diffuses toward the fourth ferromagnetic layer 3. The diffusion of boron promotes a rearrangement of atoms in each layer, and promotes crystallization of the layers.

At the time of film formation, each layer located above the fourth ferromagnetic layer 3 is amorphous. That is, the metal oxide layer 4, the third ferromagnetic layer 5, the second ferromagnetic layer 6, the non-magnetic metal layer 7, and the first ferromagnetic layer 8 are formed to be amorphous. These layers are amorphous because they are formed on the fourth ferromagnetic layer 3 that is amorphous.

Next, the laminated body layered on the substrate is annealed. The annealing temperature is, for example, 300° C. or lower, and is, for example, 250° C. or higher and 300° C. or lower.

When the laminated body is annealed, the metal oxide layer 4 is crystallized and turns into a spinel crystal. The crystallized metal oxide layer 4 becomes a core of crystallization, and the third ferromagnetic layer 5, the second ferromagnetic layer 6, the non-magnetic metal layer 7, and the first ferromagnetic layer 8 are crystallized. Since the metal oxide layer 4 becomes the core of crystallization, the layers above the metal oxide layer 4 are continuously crystallized. Moreover, boron contained in the third ferromagnetic layer 5 is attracted to Ta and the like contained in the fourth ferromagnetic layer 3 during annealing and diffuses toward the fourth ferromagnetic layer 3. The diffusion of boron promotes rearrangement of atoms in each layer, and promotes crystallization of the layers.

In a method for manufacturing the magneto-resistive element 10 according to the present embodiment, the first ferromagnetic layer 8 and the second ferromagnetic layer 6 are crystallized at a low temperature of 300° C. or lower. If the temperature is 300° C. or lower, even if annealing is performed after components other than the magnetic head are manufactured, adverse effects on other components (for example, magnetic shield) can be reduced. Therefore, a timing for performing annealing is not limited, making it easier to manufacture elements such as magnetic heads.

Moreover, in the magneto-resistive element 10 according to the present embodiment, the metal oxide layer 4 serves as a core of crystal growth, so that the first ferromagnetic layer 8 and the second ferromagnetic layer 6 sandwiching the non-magnetic metal layer 7 have high crystal properties. When the crystal properties of the first ferromagnetic layer 8 and the second ferromagnetic layer 6 increase, a spin polarization of the first ferromagnetic layer 8 and the second ferromagnetic layer 6 increases. In addition, when lattice matching at each interface of the magneto-resistive element 10 is high, scattering of spins is suppressed. For this reason, the magneto-resistive element 10 according to the present embodiment shows a high MR ratio.

Moreover, the magneto-resistive element 10 according to the present embodiment has a bottom pin structure in which the second ferromagnetic layer 6, which is a magnetization fixed layer, is closer to the substrate 1 than the first ferromagnetic layer 8, which is a magnetization free layer. The magneto-resistive element 10 in the bottom pin structure is easily applied to a read head for a hard disk.

Moreover, the magneto-resistive element 10 according to the present embodiment does not have a MgO layer and has a low RA.

Although the first embodiment has been described in detail with reference to the drawings, each constituent and combination thereof are merely examples, and additions, omissions, substitutions, and other changes of the constituents may be made within a range not departing from the gist of the present disclosure.

The magneto-resistive element 10 described above can be used for various purposes. The magneto-resistive element 10 can be applied to, for example, a magnetic head, a magnetic sensor, a magnetic memory, a high frequency filter, and the like.

Next, an application example of the magneto-resistive element according to the present embodiment will be described. Note that although the magneto-resistive element 10 is used in the following application example, the magneto-resistive element is not limited to this.

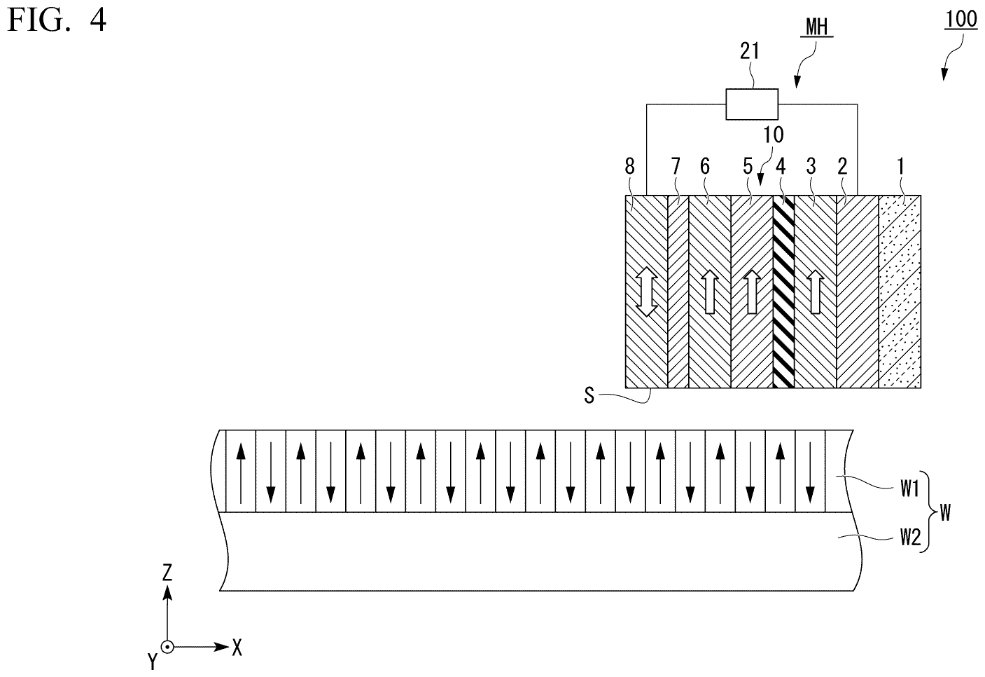

FIG. 4 is a cross-sectional view of the magnetic recording element 100 according to Application Example 1. FIG. 4 is a cross-sectional view of the magneto-resistive element 10 taken along the lamination direction.

As shown in FIG. 4, the magnetic recording element 100 includes a magnetic head MH and a magnetic recording medium W. In FIG. 4, one direction in which the magnetic recording medium W extends is defined as an X direction, and a direction perpendicular to the X direction is defined as a Y direction. An XY plane is parallel to a main surface of the magnetic recording medium W. A direction that connects the magnetic recording medium W and the magnetic head MH and is perpendicular to the XY plane is a Z direction.

The magnetic head MH has an air bearing surface (medium facing surface) S facing a surface of the magnetic recording medium W. The magnetic head MH moves along the surface of the magnetic recording medium W in directions of an arrow +X and an arrow −X at a position a certain distance away from the magnetic recording medium W. The magnetic head MH includes the magneto-resistive element 10 that functions as a magnetic sensor and a magnetic recording unit (not shown). The resistance measurer 21 measures a resistance value of the magneto-resistive element 10 in the lamination direction.

The magnetic recording unit applies a magnetic field to the recording layer W1 of the magnetic recording medium W, and determines a direction of magnetization of the recording layer W1. That is, the magnetic recording unit performs magnetic recording on the magnetic recording medium W. The magneto-resistive element 10 reads magnetization information written in the recording layer W1 by the magnetic recording unit.

The magnetic recording medium W has a recording layer W1 and a backing layer W2. The recording layer W1 is a part that performs magnetic recording, and the backing layer W2 is a magnetic path (magnetic flux path) that circulates magnetic flux for writing back to the magnetic head MH. The recording layer W1 records magnetic information as a direction of magnetization.

The second ferromagnetic layer 6 of the magneto-resistive element 10 is a magnetization fixed layer, and the direction of magnetization is fixed to the +Z direction. The first ferromagnetic layer 8 of the magneto-resistive element 10 is a magnetization free layer. For this reason, the first ferromagnetic layer 8 exposed on the air bearing surface S is influenced by the magnetization recorded in the recording layer W1 of the opposing magnetic recording medium W. For example, in FIG. 4, the magnetization direction of the first ferromagnetic layer 8 is directed to the +Z direction under the influence of the magnetization directed in the +Z direction of the recording layer W1. In this case, the magnetization directions of the second ferromagnetic layer 6 and the first ferromagnetic layer 8, which are magnetization fixed layers, are parallel to each other.

Here, a resistance when the magnetization directions of the first ferromagnetic layer 8 and the second ferromagnetic layer 6 are parallel is different from a resistance when the magnetization directions of the first ferromagnetic layer 8 and the second ferromagnetic layer 6 are antiparallel. As a difference between the resistance value in the case of being parallel and the resistance value in the case of being antiparallel increases, the MR ratio of the magneto-resistive element 10 increases. The magneto-resistive element 10 according to the present embodiment includes a Heusler alloy and has high lattice matching between layers, so that it has a large MR ratio. Therefore, the resistance measurer 21 can accurately read information on the magnetization of the recording layer W1 as a change in resistance value.

A shape of the magneto-resistive element 10 of the magnetic head MH is not particularly limited. For example, to avoid an influence of a leakage magnetic field of the magnetic recording medium W on the second ferromagnetic layer 6 of the magneto-resistive element 10, the second ferromagnetic layer 6 may be installed at a position away from the magnetic recording medium W.

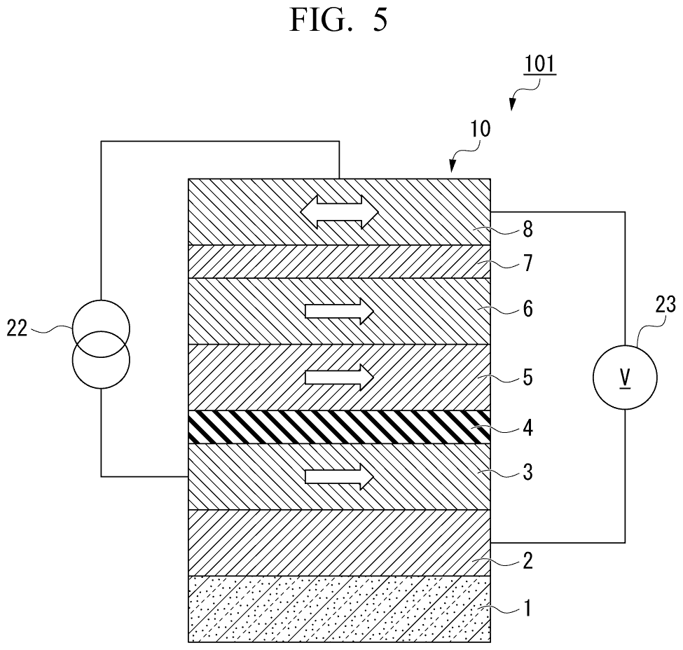

FIG. 5 is a cross-sectional view of the magnetic recording element 101 according to Application example 2. FIG. 5 is a cross-sectional view of the magnetic recording element 101 taken along the lamination direction.

As shown in FIG. 5, the magnetic recording element 101 includes a magneto-resistive element 10, a power supply 22, and a measurement unit 23. The power supply 22 applies a potential difference in the lamination direction of the magneto-resistive element 10. The power supply 22 is, for example, a DC power supply. The measurement unit 23 measures the resistance value of the magneto-resistive element 10 in the lamination direction.

If a potential difference occurs between the first ferromagnetic layer 8 and the second ferromagnetic layer 6 by the power supply 22, a current flows in the lamination direction of the magneto-resistive element 10. The current becomes spin-polarized when it passes through the second ferromagnetic layer 6, and becomes a spin-polarized current. The spin-polarized current reaches the first ferromagnetic layer 8 via the non-magnetic metal layer 7. The magnetization of the first ferromagnetic layer 8 is reversed in response to spin transfer torque (STT) caused by the spin-polarized current. By changing a relative angle between the magnetization direction of the first ferromagnetic layer 8 and the magnetization direction of the second ferromagnetic layer 6, the resistance value of the magneto-resistive element 10 in the lamination direction changes. The resistance value of the magneto-resistive element 10 in the lamination direction is read by the measurement unit 23. That is, the magnetic recording element 101 shown in FIG. 5 is a spin transfer torque (STT) type magnetic recording element.

The magnetic recording element 101 shown in FIG. 5 includes a Heusler alloy and has high lattice matching between each layer, so that it has a large MR ratio. If the MR ratio of the magneto-resistive element 10 is large, data can be recorded accurately.

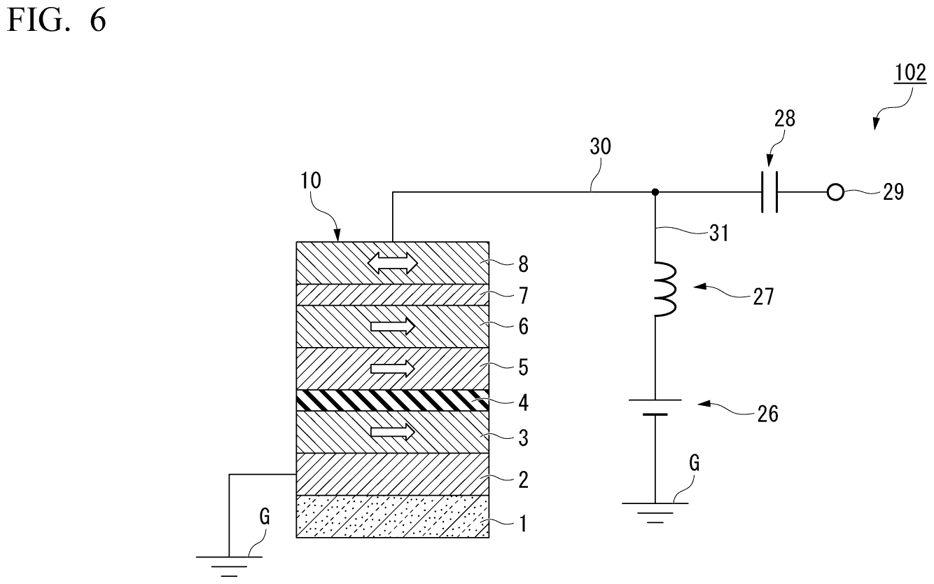

FIG. 6 is a schematic diagram of the high frequency device 102 according to Application Example 4. As shown in FIG. 6, the high frequency device 102 includes a magneto-resistive element 10, a DC power supply 26, an inductor 27, a capacitor 28, an output port 29, and wirings 30 and 31.

A wiring 30 connects the magneto-resistive element 10 and the output port 29. A wiring 31 branches from the wiring 30 and reaches a ground G via the inductor 27 and the DC power supply 26. As the DC power supply 26, the inductor 27, and the capacitor 28, known ones can be used. The inductor 27 cuts the high frequency components of a current and transmits constant components of the current. The capacitor 28 transmits high frequency components of the current and cuts constant components of the current. The inductor 27 is placed in a portion where it is desired to suppress a flow of a high frequency current, and the capacitor 28 is placed in a portion where it is desired to suppress a flow of a DC current.

When an alternating current or an alternating magnetic field is applied to a ferromagnetic layer included in the magneto-resistive element 10, the magnetization of the first ferromagnetic layer 8 precesses. The magnetization of the first ferromagnetic layer 8 strongly oscillates when a frequency of the high-frequency current or high-frequency magnetic field applied to the first ferromagnetic layer 8 is near a ferromagnetic resonance frequency of the first ferromagnetic layer 8, and it oscillates less at frequencies away from the ferromagnetic resonance frequency of the first ferromagnetic layer 8. This phenomenon is referred to as a ferromagnetic resonance phenomenon.

A resistance value of the magneto-resistive element 10 changes due to a vibration of the magnetization of the first ferromagnetic layer 8. The DC power supply 26 applies a direct current to the magneto-resistive element 10. The direct current flows in the lamination direction of the magneto-resistive element 10. The direct current flows to the ground G through wirings 30 and 31 and the magneto-resistive element 10. A potential of the magneto-resistive element 10 changes according to a law of Ohm. A high frequency signal is output from the output port 29 in response to a change in potential (change in resistance value) of the magneto-resistive element 10.

The high frequency device 102 shown in FIG. 6 includes a magneto-resistive element 10 that includes a Heusler alloy and has a large change range in resistance value, so that it can transmit a high frequency signal with a large output.

### EXAMPLE

### Example 1

As Example 1, a magneto-resistive element 10 shown in FIG. 1 was produced. Abase layer was formed between a substrate and an antiferromagnetic layer, and a cap layer was formed on a first ferromagnetic layer. The base layer includes a first base layer and a second base layer. A composition of each layer at a time of film formation was as follows.
Substrate: silicon with thermal oxide film
First base layer: Ta, film thickness 3 nm
Second base layer: Ru, film thickness 3 nm
Antiferromagnetic layer: IrMn
Fourth ferromagnetic layer: Co—Fe—B—Ta, amorphous, film thickness 3 nm
Metal oxide layer: Mg—Al—O, amorphous, film thickness 1 nm
Third ferromagnetic layer: Co—Fe—B, amorphous, film thickness 4 nm
Second ferromagnetic layer: Co₂Fe_{0.9}Ga_{0.5}Ge_{0.9}, amorphous, film thickness 4 nm
Non-magnetic metal layer: Ag, amorphous, film thickness 4 nm
First ferromagnetic layer: Co₂Fe_{0.9}Ga_{0.5}Ge_{0.9}, amorphous, film thickness 4 nm
Cap layer: Ta, film thickness 3 nm

The film-formed laminated body was annealed. Annealing, also referred to as magnetic field heat treatment, was performed in a magnetic field. To impart magnetic anisotropy such as uniaxial magnetic anisotropy, annealing was performed at 270° C. for 12 hours while applying a magnetic field. The metal oxide layer was crystallized due to annealing, and a layer above the metal oxide was also crystallized. A structure of each layer after film formation will be shown below.
Substrate: silicon with thermal oxide film
First base layer: Ta, film thickness 3 nm
Second base layer: Ru, film thickness 3 nm
Antiferromagnetic layer: IrMn
Fourth ferromagnetic layer: Co—Fe—B—Ta, amorphous, film thickness 3 nm
Metal oxide layer: Mg—Al—O, spinel crystal, film thickness 1 nm
Third ferromagnetic layer: Co—Fe, (100) oriented crystal, film thickness 4 nm
Second ferromagnetic layer: Co₂Fe_{0.9}Ga_{0.5}Ge_{0.9}, (100) oriented crystal, film thickness 4 nm
Non-magnetic metal layer: Ag, (100) oriented crystal, film thickness 4 nm
First ferromagnetic layer: Co₂Fe_{0.9}Ga_{0.5}Ge_{0.9}, (100) oriented crystal, film thickness 4 nm
Cap layer: Ta, film thickness 3 nm

A cross section of the magneto-resistive element 10 is photographed using a transmission electron microscope (TEM) image, and it was confirmed that at least a part of the metal oxide layer, the third ferromagnetic layer, the second ferromagnetic layer, the non-magnetic metal layer, and the first ferromagnetic layer are continuously crystallized.

The MR ratio and RA of the magneto-resistive element 10 of Example 1 were measured. The MR ratio is used to measure a resistance value change of the magneto-resistive element 10 by monitoring a voltage applied to the magneto-resistive element 10 according to a voltmeter while sweeping a magnetic field from the outside to the magneto-resistive element 10 with a constant current flowing in the lamination direction of the magneto-resistive element. A resistance value when the magnetization directions of the first ferromagnetic layer and the second ferromagnetic layer are parallel, and a resistance value when the magnetization directions of the first ferromagnetic layer and the second ferromagnetic layer are antiparallel are measured, and the RA is calculated according to the formula below based on the obtained resistance values. The MR ratio was measured at 300K (room temperature).

$$MR ratio ( \% ) = ( {R}_{A {P}^{-}} {R}_{P} ) / {R}_{P} \times 100$$

R_{P} is a resistance value when the magnetization directions of the first ferromagnetic layer and the second ferromagnetic layer are parallel, and RAP is a resistance value when the magnetization directions of the first ferromagnetic layer and the second ferromagnetic layer are antiparallel.

RA was obtained by a product of the resistance R_{P} when the magnetization directions of the first ferromagnetic layer and the second ferromagnetic layer are parallel and an area A of the magneto-resistive element 10 in an in-plane direction.

The MR ratio of the magneto-resistive element 10 according to Example 1 was 23%, and the RA was 0.10 Ω·μm².

### Comparison Example 1

Comparison Example 1 differs from Example 1 in that the metal oxide layer is MgO. MgO is easily oriented (100), and a portion of a film was crystallized when the film was formed on the fourth ferromagnetic layer. With the crystallization of the metal oxide layer, a part of the third ferromagnetic layer, the second ferromagnetic layer, the non-magnetic metal layer, and the first ferromagnetic layer were crystallized before annealing.

A cross section of the magneto-resistive element of Comparison Example 1 was photographed using a transmission electron microscope (TEM). Although a part of the metal oxide layer, the third ferromagnetic layer, the second ferromagnetic layer, the non-magnetic metal layer, and the first ferromagnetic layer were continuously crystallized, the ratio was smaller than in Example 1. It is considered that a part of MgO, which is a metal oxide layer, was crystallized at a time of film formation, so that chain crystallization during annealing was less likely to occur.

The MR ratio and RA of the magneto-resistive element of Comparison Example 1 were measured. The MR ratio of the magneto-resistive element according to Comparison Example 1 was 12%, and the RA was 0.22 Ω·μm².

The magneto-resistive element of Comparison Example 1 has a larger RA than the magneto-resistive element of Example 1. This is considered to be because the magneto-resistive element in Comparison Example 1 has a MgO layer. Moreover, the magneto-resistive element of Comparison Example 1 has a lower MR ratio than the magneto-resistive element of Example 1. This is considered to be because the magneto-resistive element of Comparison Example 1 has lower crystal continuity than the magneto-resistive element of Example 1.

### EXPLANATION OF REFERENCES

1 Substrate
2 Antiferromagnetic layer
3 Fourth ferromagnetic layer
4 Metal oxide layer
5 Third ferromagnetic layer
6 Second ferromagnetic layer
7 Non-magnetic metal layer
8 First ferromagnetic layer
10 Magneto-resistive element
21 Resistance measurer
22 Power supply
23 Measurement unit
26 DC Power supply
27 Inductor
28 Capacitor
29 Output port
30, 31 Wiring
100, 101 Magnetic recording element
103 High frequency device

What is claimed is:

1. A magneto-resistive element comprising:
a substrate, a first ferromagnetic layer, a non-magnetic metal layer, a second ferromagnetic layer, a third ferromagnetic layer, a metal oxide layer, a fourth ferromagnetic layer, and an antiferromagnetic layer,
wherein the first ferromagnetic layer includes a Heusler alloy containing Co,
the non-magnetic metal layer is located between the first ferromagnetic layer and the second ferromagnetic layer in a lamination direction,
the second ferromagnetic layer includes a Heusler alloy containing Co, and is closer to the substrate than the first ferromagnetic layer,
the third ferromagnetic layer is located between the second ferromagnetic layer and the metal oxide layer in the lamination direction,
the metal oxide layer has a spinel crystal structure and is located between the third ferromagnetic layer and the fourth ferromagnetic layer in the lamination direction,
the fourth ferromagnetic layer is amorphous, contains B and Ta, and is located between the metal oxide layer and the antiferromagnetic layer in the lamination direction, and
at least a part of the metal oxide layer, the third ferromagnetic layer, the second ferromagnetic layer, the non-magnetic metal layer, and the first ferromagnetic layer are continuously crystallized.

2. The magneto-resistive element according to claim 1, wherein a part of the metal oxide layer, the third ferromagnetic layer, the second ferromagnetic layer, the non-magnetic metal layer, and the first ferromagnetic layer, which are continuously crystallized, are oriented in a (100) direction.

3. The magneto-resistive element according to claim 1, wherein the Heusler alloy containing Co has an L2₁ structure or a B2 structure.

4. The magneto-resistive element according to claim 1,
wherein the third ferromagnetic layer contains Co and Fe, and
the fourth ferromagnetic layer contains Co, Fe, B, and Ta.

5. The magneto-resistive element according to claim 1, wherein a film thickness of the third ferromagnetic layer is 1.5 nm or more.

6. The magneto-resistive element according to claim 1, wherein a film thickness of the metal oxide layer is thinner than a film thickness of the non-magnetic metal layer.

7. The magneto-resistive element according to claim 1, wherein the film thickness of the metal oxide layer is 1.5 nm or less.

8. The magneto-resistive element according to claim 1, wherein resistivity of the metal oxide layer is higher than resistivity of the non-magnetic metal layer.

9. The magneto-resistive element according to claim 1, wherein a barrier height of the metal oxide layer is lower than that of a MgO layer having the same film thickness as the metal oxide layer.

10. The magneto-resistive element according to claim 1, wherein a metal oxide having a spinel crystal structure has a ratio of oxygen in a composition formula that is higher than a total ratio of metal elements when expressed in a stoichiometric composition in the metal oxide layer.

11. The magneto-resistive element according to claim 1,
wherein a concentration of B in a first surface of the fourth ferromagnetic layer is higher than a concentration of B in a second surface, and
the first surface is a surface in contact with the metal oxide layer, and the second surface is a surface opposite to the first surface.

12. The magneto-resistive element according to claim 1, wherein the non-magnetic metal layer contains Ag or Cu.

13. The magneto-resistive element according to claim 1,
wherein the Heusler alloy containing Co is expressed as Co₂Y_{α}Z_{β},
Y is one or more elements selected from the group consisting of Fe, Mn, and Cr,
Z is one or more elements selected from the group consisting of Si, Al, Ga, and Ge, and
α+β>2 is satisfied.
